(19) United States
(12) Patent Application Publication
(10) Pub. No.: US 2005/0230082 A1
(43) Pub. Date: Oct. 20, 2005

(54) Thermal interface material and method for manufacturing same

(75) Inventor: Ga-Lane Chen, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 10/996,853

(22) Filed: Nov. 24, 2004

(30) Foreign Application Priority Data
Apr. 15, 2004 (CN) 200410026921.1

(51) Int. Cl. H05K 7/20

(52) U.S. Cl. 165/80.3; 165/185; 361/704

(57) ABSTRACT

A thermal interface material (10) includes a shape memory effect thin film (12), and a thermal grease (13) attached on the film. The film is composed of a shape memory alloy, and is formed on a base (21) of a heat sink (20) at an operating temperature of a heat-generating electronic device (30). This is done by vacuum sputtering deposition or a like process. The shape memory alloy is a nano-NiTiCu alloy or a like alloy. In use, the thermal interface material enhances the thermal contact between the electronic device and the heat sink. A method for manufacturing the thermal interface material includes: (a) providing a base which is a portion of a heat sink; (b) depositing a film of a shape memory alloy on a surface of the base at an operating temperature of a heat source and under vacuum; and (c) applying a thermal grease on the film.

### BACKGROUND OF THE INVENTION

1. Field of the Invention

The invention relates generally to thermal interface materials and manufacturing methods thereof; and more particularly to a kind of thermal interface material which enhances contact between a heat source and a heat dissipating device, and a manufacturing method thereof.

2. Description of Related Art

Electronic components such as semiconductor chips are becoming progressively smaller, and the operating speeds thereof are becoming progressively higher. Correspondingly, the heat dissipation requirements of these components are increasing too. In many contemporary applications, a heat dissipating device is fixed on or near the electronic component to dissipate heat therefrom. Generally, however, there is a clearance between the heat dissipating device and the electronic component. The heat dissipating device does not engage with the electronic component compactly. Therefore, the heat produced in the electronic component cannot be efficiently transmitted to the heat dissipating device for dissipation to the external environment.

In order to enhance the contact between the heat dissipating device and the electronic component, a thermal interface material can be utilized between the electronic component and the heat dissipating device. Commonly, the thermal interface material is thermal grease. The thermal grease is compressible, and has high thermal conductivity. Furthermore, a material having high thermal conductivity can be mixed in with the thermal grease to improve the heat conducting efficiency of the thermal grease. However, when the thermal grease absorbs the heat produced by the electronic component, the temperature thereof rises, and the thermal grease is transformed. This results in incomplete contact between the heat dissipating device and the thermal grease, thus reducing the heat conducting efficiency of the thermal grease.

In order to improve the heat conducting efficiency of thermal interface materials, one approach is to reduce thermal interface resistance. Thermal interface resistance is directly proportional to a size of a thermal interface gap. Typically, there is an interface resistance between the electronic component and the thermal interface material, and an interface resistance between the thermal interface material and the heat dissipating device. One means to reduce an interface resistance is to reduce the thermal interface gap size. U.S. Pat. No. 6,294,408 discloses a method for controlling a thermal interface gap distance. In the method, by applying a force at room temperature, a thermal interface material is compressed to its final thickness, and is disposed between a circuit chip and a substantially flat thermally conductive lid. The thickness is the desired thickness for the thermal gap.

In the above-described method, the thermal interface material is compressed at room temperature. However, when the circuit chip, the thermally conductive lid and the thermal interface material heat up to an operating temperature of the circuit chip, they expand at different rates and change shape differently. Usually, the thermal gap between the thermal interface material and the thermally conductive lid is thereby enlarged. The resistance of the thermal interface material is increased, and the heat conducting efficiency of the thermal interface material is reduced.

Another approach to improving the heat conducting efficiency of thermal interface materials is to provide a kind of compliant and crosslinkable thermal interface material. U.S. Pat. No. 6,605,238 discloses this kind of thermal interface material. The thermal interface material is used for an electronic device, and comprises a silicone resin mixture and a thermally conductive filler. The filler comprises at least one of: (a) silver, copper, aluminum, and alloys thereof; (b) boron nitride, aluminum nitride, aluminum spheres, silver coated copper, silver coated aluminum, and carbon fibers; and (c) mixtures thereof. The amount of the filler is up to 95% of a total amount of the filler and the resin mixture. Because liquid silicone resins cross link to form a soft gel upon heat activation, the thermal performance of the thermal interface material does not degrade even after much thermal cycling of the electronic device.

However, in the above-described thermal interface material, the relative amount of the resin mixture is very small. Thus the resin mixture has a low viscosity, and cannot efficiently retain the filler therein. This reduces the heat conducting efficiency and performance of the thermal interface material.

A new thermal interface material which overcomes the above-mentioned problems and a method for manufacturing such material are desired.

### BRIEF SUMMARY OF THE INVENTION

Accordingly, an object of the present invention is to provide a thermal interface material having excellent heat conduction.

Another object of the present invention is to provide a method for manufacturing the above-described thermal interface material.

To achieve the first of the above-mentioned objects, the present invention provides a thermal interface material comprising a shape memory effect thin film and a thermal grease attached on the film. The film is composed of a shape memory alloy, and is formed on a surface of a base of a heat dissipating device at an operating temperature of a heat source such as an electronic device. This formation is done by way of vacuum sputtering deposition or a like process. The shape memory alloy is selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy. Diameters of particles of the shape memory alloy are in the range from 10 to 100 nanometers. In a preferred embodiment, the diameters of the particles of the shape memory alloy are in the range from 20 to 40 nanometers. A thickness of the film is in the range from 100 to 2000 nanometers. In the preferred embodiment, the thickness of the film is in the range from 500 to 1000 nanometers. The thermal grease can be a silver colloid or a silicon colloid.

To achieve the second of the above-mentioned objects, a method for manufacturing the thermal interface material comprises the steps of:
(a) providing a base which is a portion of a heat dissipating device;
(b) depositing a film of a shape memory alloy on a surface of the base at an operating temperature of a heat source and under vacuum; and
(c) applying a thermal grease on the film, the thermal grease compactly engaging with the film.

Unlike in a conventional thermal interface material, the thermal interface material of the present invention comprises the film composed of the shape memory alloy, the shape memory alloy comprising one or more nano-alloys. Thus the thermal interface material has the Shape Memory Effect, and can have a large surface area. The shape memory alloy is deposited on and compactly engages with the base of the dissipating device at the operating temperature of the heat source. In use, the temperature of the thermal interface material rises to the operating temperature, and the film recovers its original shape and can engage with the base compactly. This ensures excellent contact between the thermal interface material and the heat dissipating device. Thus the thermal interface material provides an excellent thermal path between the electronic device and the heat dissipating device.

Other objects, advantages and novel features of the invention will become more apparent from the following detailed description when taken in conjunction with the accompanying drawings, in which:

### BRIEF DESCRIPTION OF THE DRAWINGS

FIG. 1 is an inverted, isometric view of a thermal interface material of the present invention formed on a base of a heat sink;

FIG. 2 is an enlarged view of a marked portion II of FIG. 1;

FIG. 3 is an isometric view of the thermal interface material of the present invention sandwiched between an electronic device and the heat sink;

FIG. 4 is an enlarged, schematic cross-sectional view showing a compact contact state between the thermal interface material and the base of the heat sink at the time when the thermal interface material is formed;

FIG. 5 is similar to FIG. 4, but showing an incompact contact state between the thermal interface material and the base when the thermal interface material is not in use;

FIG. 6 is essentially the same as FIG. 4, showing a compact contact state between the thermal interface material and the base when the thermal interface material is in use; and

FIG. 7 is a flow chart showing a process of manufacturing the thermal interface material of the present invention.

### DESCRIPTION OF THE PREFERRED EMBODIMENTS

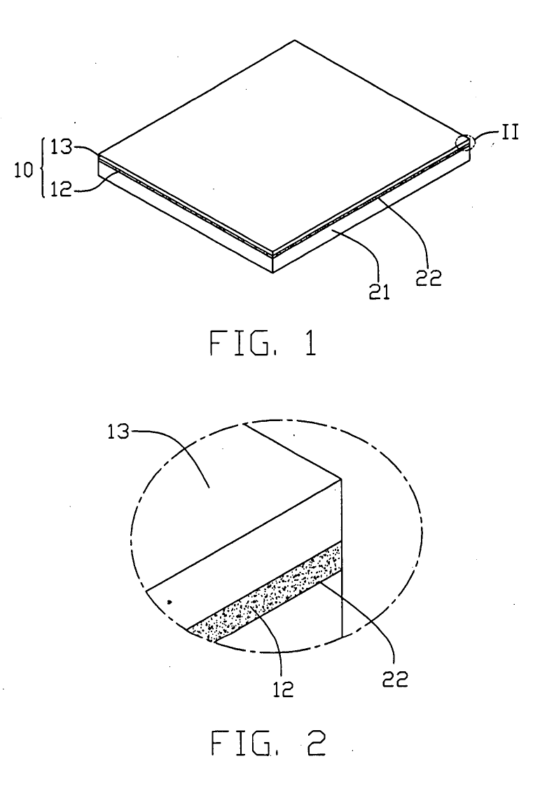

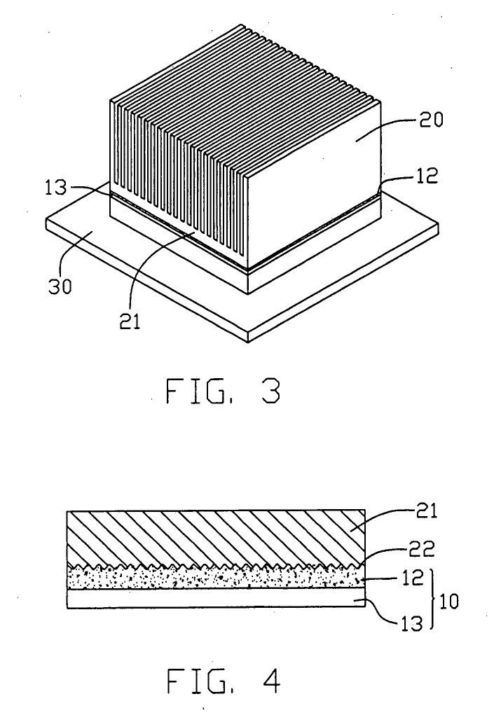

Referring to FIG. 1, a thermal interface material 10 formed on a surface 22 of a base 21 is shown. Referring also to FIG. 3, the base 21 is a portion of a heat sink 20. The thermal interface material 10 comprises a shape memory effect thin film 12, and a thermal grease 13 attached on the film 12. The film 12 is composed of a shape memory alloy, and is formed on the surface 22 of the base 21 by vacuum sputtering deposition at an operating temperature of an electronic device 30. The electronic device 30 is a heat-generating component such as a computer chip. The film 12 engages with the base 21 compactly. The shape memory alloy is a nano-alloy selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy. In the preferred embodiment, the shape memory alloy is a nano-NiTiCu alloy. The above-mentioned nano-alloys have high thermal interface conductivities. Diameter of particles of the shape memory alloy are in the range from 10 to 100 nanometers. In the preferred embodiment, the diameters of the particles of the shape memory alloy are in the range from 20 to 40 nanometers. A thickness of the film 12 is in the range from 100 to 2000 nanometers. In the preferred embodiment, the thickness of the film 12 is in the range from 500 to 1000 nanometers. The thermal grease is a silver colloid or a silicon colloid.

The film 12 has the Shape Memory Effect (SME). U.S. Pat. No. 6,689,486 discloses details of the Shape Memory Effect. The Shape Memory Effect occurs when a shape memory alloy undergoes a phase transformation from a low temperature martensitic phase to a high temperature austenitic phase. In the martensitic phase, the material is deformed by preferential alignment of twins. Unlike permanent deformations associated with dislocations, deformation of the material due to twinning is fully recoverable when the material is heated to the austenitic phase. Reversibly, the Shape Memory Effect occurs when the shape memory alloy undergoes a phase transformation from the high temperature austenitic phase to the low temperature martensitic phase.

The film 12 of the present invention is formed at the operating temperature of the electronic device 30, and has the above-mentioned Shape Memory Effect. The film 12 deforms at a low temperature such as room temperature, and in the deformed state does not engage with the base 21 compactly. When the thermal interface material 10 is in use, the shape memory alloy 12 recovers its original shape and engages with the base 21 compactly. This ensures that heat produced by the electronic device 30 can be dissipated efficiently.

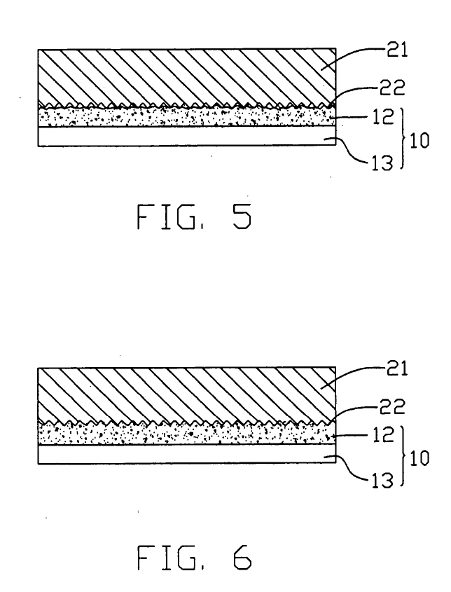

Details of contact states between the thermal interface material 10 and the base 21 are shown in FIGS. 4, 5 and 6. FIG. 4 is an enlarged, cross-sectional view showing a compact contact state between the thermal interface material 10 and the base 21 at the time when the film 12 is formed at the operating temperature of the electronic device 30. At this state, the shape memory alloy is in the high temperature austenitic phase, and the film 12 is engaged with the surface 22 of the base 21 compactly. FIG. 5 is an enlarged, cross-sectional view showing an incompact contact state between the thermal interface material 10 and the base 21 when the thermal interface material 10 is not in use. At this state, the temperature of the thermal interface material 10 is the same as the temperature of the external environment, which is lower than the operating temperature of the electronic device 30. Thus the shape memory alloy 12 is in the low temperature martensitic phase, and the film 12 is deformed. Accordingly, the film 12 cannot engage with the base 21 compactly. FIG. 6 is an enlarged, cross-sectional view showing a compact contact state between the thermal interface material 10 and the base 21 when the thermal interface material 10 is in use. In reaching this state, the temperature of the thermal interface material 10 rises, and the shape memory alloy undergoes a phase transformation from the low temperature martensitic phase to the high temperature austenitic phase. Thus the film 12 recovers its shape and can engage with the base 21 compactly.

FIG. 3 shows the application environment of the thermal interface material 10 of the present invention. The thermal interface material 10 is disposed between the heat sink 20 and the electronic device 30 to provide good heat contact between the heat sink 20 and the electronic device 30. The film 12 of the thermal interface material 10 abuts against the base 21 of the heat sink 20, and the thermal grease 13 of the thermal interface material 10 engages with the electronic device 30. When the electronic device 30 is in use, it typically produces much heat. The heat is transmitted to the thermal grease 13, the film 12 and the heat sink 20 in turn. In this process, the temperature of the thermal interface material 10 rises, and the shape memory alloy undergoes the phase transformation from the low temperature martensitic phase to the high temperature austenitic phase. Thus, the film 12 recovers its shape and engages with the base 21 compactly. Thus the thermal interface material 10 provides an excellent thermal path between the electronic device 30 and the heat sink 20, and the heat produced by the electronic device 30 can be dissipated to the external environment efficiently. The above-mentioned characteristics of the thermal interface material 10 enable it to have a large surface area.

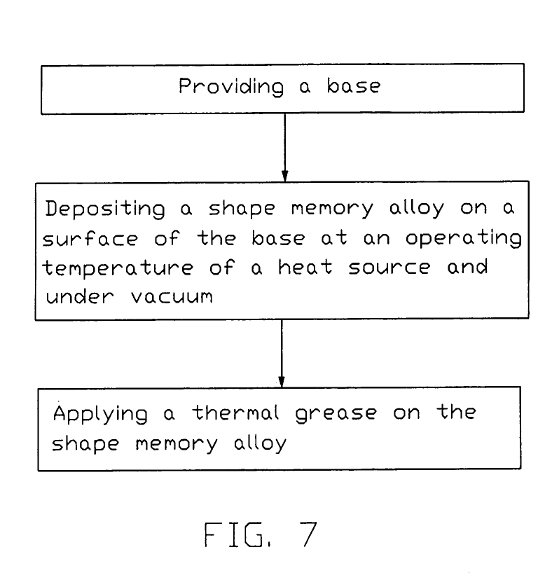

FIG. 7 is a flow chart showing a process of manufacturing the thermal interface material 10. Firstly, the base 21 is provided. The base 21 is a portion of the heat sink 20, and comprises the surface 22. Secondly, the shape memory alloy is deposited on the surface 22 of the base 21 at the operating temperature of the electronic device 30 and under vacuum, thereby forming the film 12. Thirdly, the thermal grease 13 is applied on the film 12, the thermal grease 13 being a silver colloid or a silicon colloid.

The shape memory alloy is selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy. In the preferred embodiment, the shape memory alloy is a nano-NiTiCu alloy. The second step is performed by way of Direct Current (DC) Magnetron Sputtering, Co-Sputtering, Radio Frequency (RF) Sputtering, or Pulsed Laser Deposition. In the second step, the base 21 is rotated, so that the shape memory alloy is deposited on the base 21 uniformly. A pressure of the vacuum is less than 8×10⁻⁶ torr. In the preferred embodiment, the pressure of the vacuum is 5×10⁻⁷ torr. If the electronic device 30 is a CPU (central processing unit), the operating temperature of the electronic device 30 is normally in the range from 50 to 100° C. In the preferred embodiment, the operating temperature is 90° C. In the third step, a force required to engage the thermal grease 13 with the film 12 compactly is in the range from 4.9 to 294 newton. In the preferred embodiment, the force is in the range from 98 to 137 newton.

It is understood that the above-described embodiments are intended to illustrate rather than limit the invention. Variations may be made to the embodiments without departing from the spirit of the invention. Accordingly, it is appropriate that the appended claims be construed broadly and in a manner consistent with the scope of the invention.

1. A thermal interface material comprising a film and thermal grease attached on the film;
wherein the film is composed of a shape memory alloy, and is formed on a base of a heat dissipating device.

2. The thermal interface material as claimed in claim 1, wherein the shape memory alloy is a nano-alloy.

3. The thermal interface material as claimed in claim 2, wherein the shape memory alloy is selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy.

4. The thermal interface material as claimed in claim 3, wherein diameters of particles of the shape memory alloy are in the range from 10 to 100 nanometers.

5. The thermal interface material as claimed in claim 1, wherein a thickness of the film is in the range from 100 to 2000 nanometers.

6. The thermal interface material as claimed in claim 1, wherein the thermal grease is a silver colloid or a silicon colloid.

7. A method for manufacturing a thermal interface material, the method comprising the steps of:
(a) providing a base which is a portion of a heat dissipating device;
(b) depositing a film of a shape memory alloy on the base at an operating temperature of a heat source and under vacuum; and
(c) applying thermal grease on the film, the thermal grease compactly engaging with the film.

8. The method as claimed in claim 7, wherein step (b) is performed by way of Direct Current (DC) Magnetron Sputtering, Co-Sputtering, Radio Frequency (RF) Sputtering, or Pulsed Laser Deposition.

9. The method as claimed in claim 7, wherein in step (b) the base is rotated.

10. The method as claimed in claim 7, wherein a pressure of the vacuum is less than 8×10⁻⁶ torr.

11. The method as claimed in claim 7, wherein the shape memory alloy is selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy.

12. The method as claimed in claim 7, wherein the thermal grease is a silver colloid or a silicon colloid.

13. The thermal interface material as claimed in claim 7, wherein diameters of particles of the shape memory alloy are in the range from 10 to 100 nanometers.

14. The thermal interface material as claimed in claim 7, wherein a thickness of the film is in the range from 100 to 2000 nanometers.

15. The method as claimed in claim 7, wherein a force required to engage the thermal grease with the film compactly is in the range from 4.9 to 294 newton.

16. A method for manufacturing a thermal interface material, comprising the steps of:
providing a base for bearing said thermal interface material; and
forming a thermally conductive film of a shape memory alloy on said base as a part of said thermal interface material at a predetermined temperature so as to allow said thermal interface material to perform a same attachment manner to said base under a circumstance of said predetermined temperature after said forming step.

17. The method as claimed in claim 16, further comprising the step of applying thermally conductive grease on said film as another part of said thermal interface material.

18. The method as claimed in claim 16, wherein said shape memory alloy is selected from the group consisting of a nano-NiTiCu alloy, a nano-CuAlNi alloy, a nano-CuAlZn alloy, a nano-NiTiAlCu alloy, a nano-NiTiAlZn alloy, and a nano-NiTiAlZnCu alloy.
